(19) United States
(12) Patent Application Publication
(10) Pub. No.: US 2006/0182542 A1
(43) Pub. Date: Aug. 17, 2006

(54) Manufacturing system and operative method thereof

(76) Inventors: Yao-I Tung, Taoyuan City (TW); Yu-Jen Tsai, Kaohsiung City (TW); Wei-Liang Lee, Taoyuan City (TW); Ching-Hsiang Chang, Banciao City (TW); Sung-Hsing Yeh, Yonghe City (TW)

Correspondence Address: J C PATENTS, INC., 4 VENTURE, SUITE 250, IRVINE, CA, 92618, US

(21) Appl. No.: 11/165,640

(22) Filed: Jun. 23, 2005

(30) Foreign Application Priority Data
Jan. 6, 2005 (TW) 94100338

(51) Int. Cl. H01L 21/677

(52) U.S. Cl. 414/217.1

(57) ABSTRACT

A manufacturing system is provided. The manufacturing system includes at least a handling system, two deposition apparatus groups, an etching apparatus group, a photolithography apparatus group and two photoresist-striping apparatus groups. The handling system has a plurality of handling paths comprising at least two connected ring paths, which are connected in a common path. These deposition apparatus groups and the photoresist-striping apparatus groups are located on the two ring paths respectively. The etching apparatus group is located on the common path. The photolithography apparatus group is located on the two ring paths between the two deposition apparatus groups. The manufacturing system of the present invention thus combines the advantages of the group-type manufacturing system and the continuous-type manufacturing system.

### CROSS-REFERENCE TO RELATED APPLICATION

This application claims the priority benefit of Taiwan application serial no. 94100338, filed on Jan. 6, 2005. All disclosure of the Taiwan application is incorporated herein by reference.

### BACKGROUND OF THE INVENTION

1. Field of the Invention

The present invention relates to a system and the operative method thereof. More particularly, the present invention relates to a manufacturing system and the operative method thereof adapted for the manufacturing of products requiring deposition, photolithography, etching and photoresist-striping processes.

2. Description of Related Art

The manufacturing system for the thin film transistor-liquid crystal displays (TFT-LCD) usually comprises a handling system, a deposition apparatus group, an etching apparatus group, a photolithography apparatus group and a photoresist-striping apparatus group. The group-type manufacturing system is often used in TFT-LCD field since the equipment for TFT-LCD requires precision, great cost and lower turnover rate. The group-type manufacturing system and the operative method thereof are briefly described in the following.

The conventional group-type manufacturing system comprises a handling system, a deposition apparatus group, a photolithography apparatus group, and an etching apparatus group placed in specific locations in the factory. The handling system has a plurality of longitudinal handling paths and a plurality of lateral handling paths, wherein the longitudinal handling paths are indirectly connected with each other by the lateral handling paths. The operative method of the group-type manufacturing system starts by moving substrates through the handling system to specific apparatuses to process the substrates. And then, the substrates are moved to the next apparatuses to further process the substrates. In other words, according to the group-type manufacturing system of the conventional operative method, the substrates must be moved to the manufacturing apparatuses by the longitudinal handling paths and the lateral handling paths. However, the product line of the conventional group-type manufacturing system is not fluent and may result in the following problems: (1) The in-process goods are a large amount due to the long production cycle. (2) The chance of the in-process goods being polluted is increased and the yield factor of the products is reduced due to the long handling distance among the apparatuses. (3) Ineffective handling of the in-process goods is frequent due to high reflow rate of the product line in the conventional group-type manufacturing system.

To overcome the above-mentioned disadvantages of the group-type manufacturing system, alternatively, another conventional manufacturing system, the continuous-type system, is introduced. FIG. 1 is a schematic drawing of the conventional continuous-type manufacturing system. With reference to FIG. 1, the conventional continuous-type manufacturing system 100 is adapted for manufacturing the liquid crystal display (LCD) substrates or other substrates made in semiconductor process. The manufacturing system 100 comprises at least a handling path 110, a deposition apparatus 120, a photolithography apparatus 130, an etching apparatus 140, a photoresist-striping apparatus 150 and a test apparatus 160. Wherein, the deposition apparatus 120, the photolithography apparatus 130, the etching apparatus 140, the photoresist-striping apparatus 150 and the test apparatus 160 are located on the handling path 110.

As shown in FIG. 1, the operative method of the continuous-type manufacturing system 100 follow the same steps as the conventional group-type manufacturing system, but layouts of the handling path and the deployment of the manufacturing apparatuses are different. It should be noted that the continuous-type manufacturing system can effectively overcome the disadvantages of the group-type manufacturing system, but still has the following problems: (1) A plurality of production lines are necessary for mass production; that is, it is necessary to invest heavily on the production apparatuses; and (2) The production line will stop if anyone of the apparatuses in anyone of the production lines malfunctions.

### SUMMARY OF THE INVENTION

Accordingly, the present invention is directed to providing a manufacturing system and the operative method thereof combining the advantages of the group-type and the continuous-type manufacturing systems to reduce the manufacturing cost.

In order to achieve the object described above, the present invention provides a manufacturing system comprising a handling system, two deposition apparatus groups, an etching apparatus group, a photolithography apparatus group and two photoresist-striping apparatus groups. The handling system has a plurality of handling paths, which comprise at least two ring paths, wherein the two ring paths are connected in a common path. The deposition apparatus groups and the photoresist-striping apparatus groups are located on the two ring paths respectively. The etching apparatus group is located on the common path. The photolithography apparatus group is located on the two ring paths between the two deposition apparatus groups.

In order to achieve the object described above, the present invention provides an operative method of the manufacturing system, adapted for applied in the aforementioned manufacturing system, comprising the following steps. First, in step (a), the substrate is moved to the deposition apparatus group by the handling system to deposit the substrate. And then, in step (b), the substrate is moved from the deposition apparatus group to the photolithography apparatus group for a photolithography process. Afterwards, in step (c), the substrate is moved from the photolithography apparatus group to the etching apparatus group for an etching process to form a patterned film. Next, in step (d), the substrate is moved from the etching apparatus group to the photoresist-striping apparatus group for a photoresist-striping process. And then, in step (e), the substrate is moved from the photoresist-striping apparatus group to another deposition apparatus group for another deposition process. Afterwards, in step (f), the substrate is moved from the deposition apparatus group to another photolithography apparatus group for another photolithography process. Next, in step (g), the substrate is moved from the photolithography apparatus group to another etching apparatus group for another etching process to form another patterned film. And then, in step (h), the substrate is moved from the etching apparatus group to another photoresist-striping apparatus group for another photoresist-striping process. Afterwards, the substrate is moved from the photoresist-striping apparatus group to the deposition apparatus group, and the steps (a) to (c) and the steps (e) to (g) are repeated in order to form a plurality of patterned films.

To sum up, the present invention, the manufacturing system and the operative method thereof, utilizes the two ring paths and the apparatus group disposed thereon. Therefore, the present invention combines the advantages of the group-type and the continuous-type manufacturing systems to lower the manufacturing cost. One of the advantages is that the production line will keep functioning and only a portion of the production will be lost when one of the apparatuses malfunctions in one of the production lines (the advantage of group-type manufacturing system). Also, the product lines in the present invention will be fluent so ineffective handling can be avoided (the advantage of continuous-type manufacturing system).

### BRIEF DESCRIPTION OF THE DRAWINGS

The accompanying drawings are included to provide a better understanding of the invention, and are incorporated in and constitute a part of this specification. The drawings illustrate embodiments of the invention, and together with the description, serve to explain the principles of the invention.

FIG. 1 is a schematic drawing of the conventional continuous-type manufacturing system.

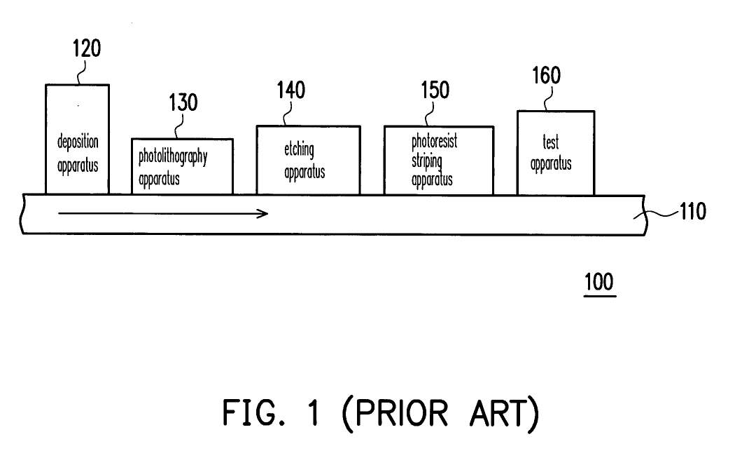

FIG. 2A is a schematic drawing of the manufacturing system in accordance with one embodiment of the present invention.

FIG. 2B is a schematic drawing of the handling system in FIG. 2A.

### DESCRIPTION OF THE EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

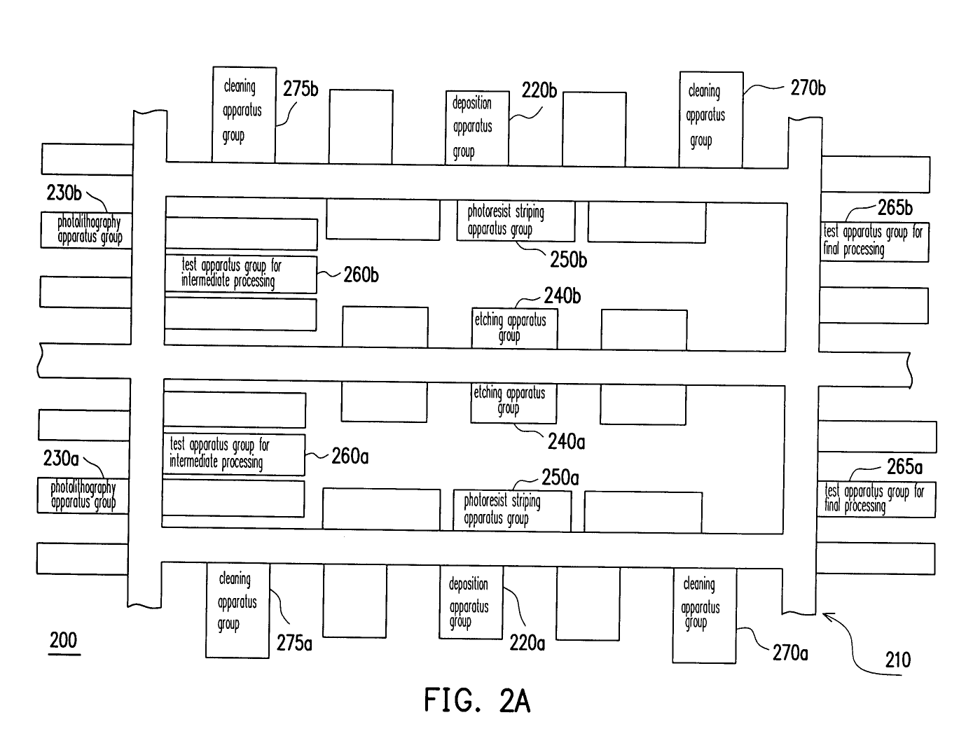

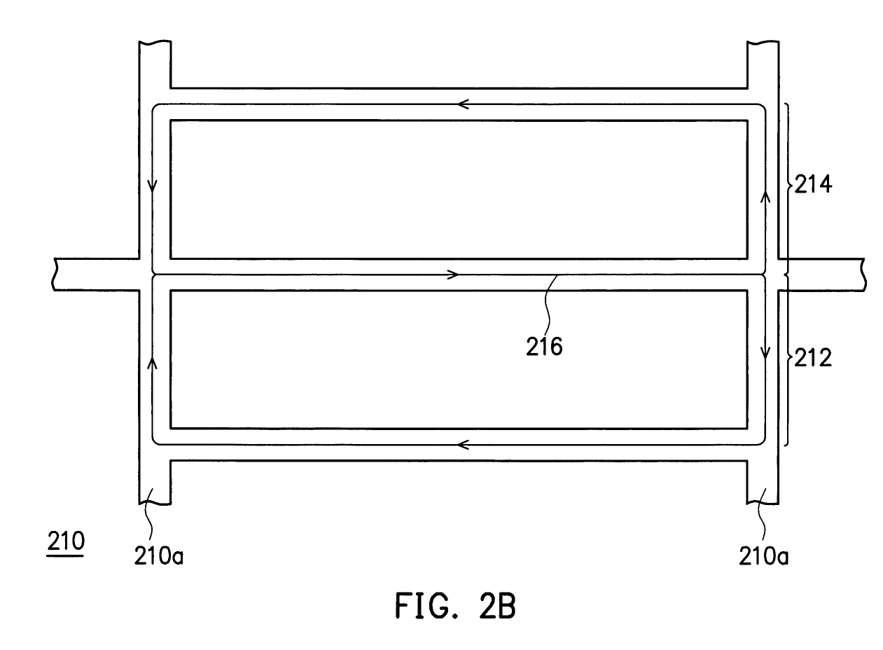

FIG. 2A is a schematic drawing of the manufacturing system in accordance with one embodiment of the present invention. FIG. 2B is a schematic drawing of the handling system in FIG. 2A. As shown in FIGS. 2A and 2B, the present invention, a manufacturing system 200, is adapted for manufacturing liquid crystal displays (LCDs) or other semiconductor elements. The manufacturing system 200 comprises at least a handling system 210, two deposition apparatus groups 220a, 220b, two photolithography apparatus groups 230a, 230b, two etching apparatus groups 240a, 240b, and two photoresist-striping apparatus groups 250a, 250b. For example, the handling system 210 is an automatic material handling system (AMHS). And the AMHS comprises at least an automatic guided vehicle (AGV), an in-line stocker or an overhead shuttle (OHS), wherein the AGV or the in-line stocker can be used in a single apparatus group, and the AGV or the OHS can be used to connect the apparatus groups. The two deposition apparatus groups 220a, 220b comprise a plurality of physical vapor deposition (PVD) or chemical vapor deposition (CVD) apparatuses. The two etching apparatus groups 240a, 240b comprise a plurality of dry etching or wet etching apparatuses.

As shown in FIGS. 2A and 2B, the handling system 210 has a plurality of handling paths 210a, which comprise at least two connected ring paths 212 and 214, wherein the connected path is a common path 216. The deposition apparatus groups 220a, 220b and the photoresist-striping apparatus groups 250a, 250b are located on the two ring paths 212, 214 respectively, and the photoresist-striping apparatus groups 250a, 250b are located adjacent to the deposition apparatus groups 220a, 220b. The two photolithography apparatus groups 230a, 230b are located on the two ring paths 212, and 214 between the two deposition apparatus groups 220a, 220b. The two etching apparatus groups 240a, 240b are located on the common path 216 respectively.

With reference to FIGS. 2A and 2B, the operative method of the manufacturing system 200 starts by moving at least a substrate (not shown) to the deposition apparatus group 220a by the handling system 210 to deposit the substrate (step 1). Next, the substrate is moved from the deposition apparatus group 220a to the photolithography apparatus group 230a for a photolithography process (step 2). And then, the substrate is moved from the photolithography apparatus group 230a to the etching apparatus group 240a or 240b for an etching process to form a patterned film (not shown) (step 3). Afterwards, the substrate is moved from the etching apparatus group 240a or 240b to the photoresist-striping apparatus group 250b for a photoresist-striping process (step 4).

With reference to FIGS. 2A and 2B, the substrate is then moved from the photoresist-striping apparatus group 250b to the deposition apparatus group 220b for another deposition process (step 5). Next, the substrate is moved from the deposition apparatus group 220b to the photolithography apparatus group 230b for a photolithography process (step 6). And then, the substrate is moved from the photolithography apparatus group 230b to the etching apparatus group 240a or 240b for another etching process to form another patterned film (not shown) (step 7). Afterwards, the substrate is moved from the etching apparatus group 240a or 240b to the photoresist-striping apparatus group 250a for a photoresist-striping process (step 8). Next, the steps 1 to 3 and the steps 5 to 7 are repeated in proper order to form a plurality of patterned films (not shown) until the predetermined process is complete.

As shown in FIGS. 2A and 2B, in one embodiment, the manufacturing system 200 further comprises two test apparatus groups 260a, 260b for intermediate processing, located on the two ring paths 212, 214 between the two deposition apparatus groups 220a, 220b respectively. In one embodiment, the test apparatus groups 260a, 260b for intermediate processing are located in the vicinity of the photolithography apparatus group 230a, 230b. If the manufacturing system 200 comprises the two test apparatus groups 260a, 260b for intermediate processing, the operative method thereof will comprise the step 4-1. The step 4-1 follows step 4, i.e. the etching process. The step 4-1 starts by moving the substrate from the photoresist-striping apparatus groups 250a or 250b to the test apparatus groups 260b, 260a for the test process.

As shown in FIGS. 2A and 2B, in one embodiment, the manufacturing system 200 further comprises two test apparatus groups 265a, 265b for final processing, located on the two ring paths 212, 214 between the deposition apparatus groups 220a, 220b respectively. In one embodiment, the test apparatus groups 265a, 265b for final processing are located in the vicinity of the two ring paths 212,214 in the right side of FIG. 2A. If the manufacturing system 200 comprises the two test apparatus groups 265a, 265b for final processing, the operative method of the manufacturing system 200 will comprise the step 9, which is performed after achieving all the above-mentioned processes. The step 9 starts by moving the substrate to the test apparatus groups 265a, 265b for final processing for the test process after completing all the other steps.

As shown in FIGS. 2A and 2B, in one embodiment, the manufacturing system 200 further comprises four cleaning apparatus groups 270a, 270b, 275a and 275b. The cleaning apparatus groups 270a, 275a and the cleaning apparatus groups 270b, 275b are located on the two ring paths 212, 214 respectively, where is in the vicinity of the two deposition apparatus groups 220a, 220b respectively. If the manufacturing system 200 comprises the four cleaning apparatus groups 270a, 270b, 275a and 275b, the operative method of the manufacturing system 200 will comprise the step 1-1 and/or step 5-1. The step 1-1 is performed after or prior to the step 1. The step 5-1 is performed after or prior to the step 5. The step 1-1 starts by moving the substrate from the deposition apparatus group 220a to the cleaning apparatus group 275a or moving the substrate from the etching apparatus group 240a or 240b to the cleaning apparatus group 270a for the cleaning process. In addition, the step 5-1 starts by moving the substrate from the deposition apparatus group 220b to the cleaning apparatus group 275b or moving the substrate from the etching apparatus group 240a or 240b to the cleaning apparatus group 270b for the cleaning process.

It should be noted that apparatus groups and the manufacturing process of the embodiments in the present invention, the manufacturing system 200 and the operative method thereof, can be applied flexibly according to different requirement. In addition, the number of ring paths of the manufacturing system 200 is not limited to two, but can also be one or more than three and still falls within the scope of the present invention.

Because the present invention, the manufacturing system 200 and the operative method thereof, has the connected two ring paths 212, 214, where in the vicinity the apparatuses are installed in group, the substrates can move along the two ring paths 212, 214, i.e. the FIG. 8 production line, to form a plurality of patterned films thereon repeating the steps, i.e. the deposition, the photolithography, the etching and the photoresist-striping process. Therefore, the present invention, the manufacturing system and the operative method thereof, has combined the advantages of the group-type and the continuous-type manufacturing systems. The advantages are described in the following:

(1) The fluent product line can avoid re-flow and inefficient handling to lower the investment cost of the apparatuses, shorten the production cycle, and reduce the number of in-process goods.

(2) The handling distances among the apparatuses are shorter so that the possibility of the in-process goods being polluted is lowered and the yield factor of the products is promoted.

(3) Compared with the conventional continuos-type manufacturing system, the present invention, the manufacturing system and the operative method thereof, can effectively decrease the number of the production apparatuses. In addition, when one machine of the apparatus groups malfunctions, only a portion of production will be lost, and the production lines will continue running.

To sum up, because the present invention, the manufacturing system and the operative method thereof, has the connected ring paths, where in the vicinity the apparatuses are installed in group, by moving along the ring paths, the substrate is continuously undergoing many processes, i.e. the deposition, the photolithography, and the etching, and the photoresist-striping process, and then a plurality of patterned films are formed thereon. Therefore, the present invention combines the advantages of the group-type and the continuous-type manufacturing systems and can effectively lower the manufacturing cost of the substrates during mass-production.

The above description provides a full and complete description of the embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A manufacturing system, comprising:
a handling system having a plurality of handling paths, which comprise at least a first ring path and a second ring path, wherein the first ring path and the second ring path is connected in a common path;
a first deposition apparatus group located on the first ring path;
an etching apparatus group located on the common path;
a second deposition apparatus group located on the second ring path;
a photolithography apparatus group located on the first ring path and the second ring path between the first deposition apparatus group and the second deposition apparatus group;
a first photoresist-striping apparatus group located on the second ring path; and
a second photoresist-striping apparatus group located on the first ring path.

2. The manufacturing system of claim 1, further comprising a test apparatus group for intermediate processing located on the first ring path and the second ring path between the first deposition apparatus group and the second deposition apparatus group.

3. The manufacturing system of claim 1, further comprising a test apparatus group for final processing located on the first ring path and the second ring path between the first deposition apparatus group and the second deposition apparatus group.

4. The manufacturing system of claim 1, wherein the first deposition apparatus group comprises a plurality of physical vapor deposition (PVD) apparatuses, a plurality of chemical vapor deposition (CVD) apparatuses or a combination thereof.

5. The manufacturing system of claim 1, further comprising a first cleaning apparatus, which is located on the first ring path in the vicinity of the first deposition apparatus group.

6. The manufacturing system of claim 1, wherein the second deposition apparatus group comprises a plurality of physical vapor deposition apparatuses, a plurality of chemical vapor deposition apparatuses or a combination thereof.

7. The manufacturing system of claim 1, further comprising a second cleaning apparatus, which is located on the second ring path in the vicinity of the second deposition apparatus group.

8. The manufacturing system of claim 1, wherein the etching apparatus group comprises a plurality of dry etching apparatuses, a plurality of wet etching apparatuses or a combination thereof.

9. The manufacturing system of claim 1, wherein the handling system comprises an automatic material handling system.

10. An operative method of manufacturing system, suitable for applied in the manufacturing system of claim 1, comprising:
(a) Moving the substrate to the first deposition apparatus group by the handling system for a first deposition process;
(b) Moving the substrate from the first deposition apparatus group to the photolithography apparatus group for a first photolithography process;
(c) Moving the substrate from the photolithography apparatus group to the etching apparatus group for a first etching process to form a first patterned film on the substrate;
(d) Moving the substrate from the etching apparatus group to the first photoresist-striping apparatus group for a first photoresist-striping process.
(e) Moving the substrate from the first photoresist-striping apparatus group to the second deposition apparatus group for a second deposition process;
(f) Moving the substrate from the second deposition apparatus group to the photolithography apparatus group for a second photolithography process;
(g) Moving the substrate from the photolithography apparatus group to the etching apparatus group for a second etching process to form a second patterned film on the substrate; and
(h) Moving the substrate from the etching apparatus group to the second photoresist-striping apparatus group for a second photoresist-striping process.

11. The operative method of manufacturing system of claim 10, further comprising moving the substrate from the second photoresist-striping apparatus group to the first deposition apparatus group, and repeating the steps (a) to (c) to form a third patterned film, and repeating the steps (e) to (g) to form a fourth patterned film.

12. The operative method of manufacturing system of claim 10, wherein after the substrate is moved from the first photoresist-striping apparatus group or the second photoresist-striping apparatus group, an intermediate testing process is performed on the substrate.

13. The operative method of manufacturing systems of claim 10, wherein after all the manufacturing processes are complete, a final testing process is performed on the substrate.

14. The operative method of manufacturing systems of claim 10, wherein before the substrate is moved to the first deposition apparatus group, a cleaning process is performed on the substrate.

15. The operative method of manufacturing systems of claim 10, wherein before the substrate is moved to the second deposition apparatus group, a cleaning step is performed on the substrate.

16. The operative method of manufacturing systems of claim 10, wherein after the substrate is moved from the first deposition apparatus group, a cleaning process is performed on the substrate.

17. The operative method of manufacturing systems of claim 10, wherein after the substrate is moved from the second deposition apparatus group, a cleaning process is performed on the substrate.
